(19) United States
(12) Patent Application Publication
(10) Pub. No.: US 2004/0051166 A1
(43) Pub. Date: Mar. 18, 2004

(54) Shielding line system for an integrated circuit

(76) Inventors: Guenter Gerstmeier, Chapel Hill, NC (US); Torsten Partsch, Chapel Hill, NC (US)

Correspondence Address: BRINKS HOFER GILSON & LIONE, P.O. BOX 10395, CHICAGO, IL, 60611, US

(21) Appl. No.: 10/246,004

(22) Filed: Sep. 18, 2002

(51) Int. Cl. H01L 23/58

(52) U.S. Cl. 257/630

(57) ABSTRACT

A shielding line system reduces or eliminates crosstalk between conductive lines in an integrated circuit. The shielding line system has first conductive line and one or more second conductive lines. A shielding line conduit radially encloses the first conductive line. An electromagnetic field also radially encloses the first conductive line.

### FIELD

This invention generally relates to integrated circuits having conductive channels or lines. More particularly, this invention relates to integrated circuits having shielding lines to reduce crosstalk and other transmission line effects.

### BACKGROUND

An integrated circuit or other semiconductor device typically has many resistors, capacitors, transistors, and/or other electrical components fabricated on a semiconductor wafer. The electrical components are interconnected by numerous conductive channels or lines formed by conductive material between the components. The conductive lines act like wires carrying electrical and other signals between the components. With a suitable configuration of electrical components and conductive lines, an integrated circuit can function as an amplifier, a microprocessor, a memory device or the like. The memory device may be a dynamic random access memory (DRAM), another type of random access memory (RAM), or another type of memory.

DRAM and other memory devices usually have an array of memory cells formed on the semiconductor wafer. Each memory cell has a configuration of transistors and capacitors that is repeated throughout the array. The memory cells store data as electronically-charged points using the capacitors and transistors. Typically, the memory cells receive new electronic charges to refresh or prevent the capacitors from losing any electrical charge.

DRAM devices have numerous conductive channels for interconnecting transistors and capacitors with each memory cell and for interconnecting memory cells and other electronic components on the semiconductor wafer. As with other integrated circuits, the conductive channels or lines are close together. Recent designs have closer conductive channels or lines to reduce the size of the DRAM device or integrated circuit.

In many DRAM and integrated circuit designs, there can be crosstalk and other transmission line effects between the conductive channels or lines. Crosstalk is the interference caused when signals in adjacent or nearby conductive channels or lines are superimposed on each other. The conductive channels or lines form an electromagnetic (inductive) or an electrostatic (capacitive) coupling, which causes the signals or voltages on one conductive channel to jump to other conductive channels. Crosstalk can be reduced by increasing the distance between the conductive channels or lines or by using shielding lines between the conductive channels or lines.

FIG. 1 is a block diagram of a shielding line system according to the prior art. Shielding lines are disposed between signal and critical lines. Signal lines usually carry data and control signals in a DRAM device. Critical lines usually carry timing signals or reference voltages. The shielding lines have constant potential, which creates an electromagnetic field between the signal and critical lines. However, crosstalk occurs when the interference between the signal and critical lines passes over or around the shielding lines and their respective electromagnetic field.

### SUMMARY

This invention provides a shielding line system that reduces or eliminates crosstalk between conductive lines in an integrated circuit. The shielding line system radially encloses a conductive line with a shielding line conduit and an electromagnetic field.

The shielding line system may have a first conductive line, one or more second conductive lines, and a shielding line conduit. The shielding line conduit is disposed between the first and second conductive lines. The shielding line conduit radially encloses the first conductive line. An electromagnetic field radially encloses the first conductive line.

The shielding line system also may have a first conductive line, a second conductive line, a third conductive line, first and second side shielding lines, and top and bottom shielding lines. The first side shielding line is disposed between the first and second conductive lines. The second side shielding line is disposed between the first and third conductive lines. The top shielding line is connected to the first and second shielding lines. The bottom shielding line is connected to the first and second shielding lines. As a result, an electromagnetic field radially encloses the first conductive line when potential is applied to the interconnected shielding lines.

Other systems, methods, features, and advantages of the invention will be or will become apparent to one skilled in the art upon examination of the following figures and detailed description. All such additional systems, methods, features, and advantages are intended to be included within this description, within the scope of the invention, and protected by the accompanying claims.

### BRIEF DESCRIPTION OF THE FIGURES

The invention may be better understood with reference to the following figures and detailed description. The components in the figures are not necessarily to scale, emphasis being placed upon illustrating the principles of the invention. Moreover, like reference numerals in the figures designate corresponding parts throughout the different views.

FIG. 1 is a block diagram of a shielding line system according to the prior art.

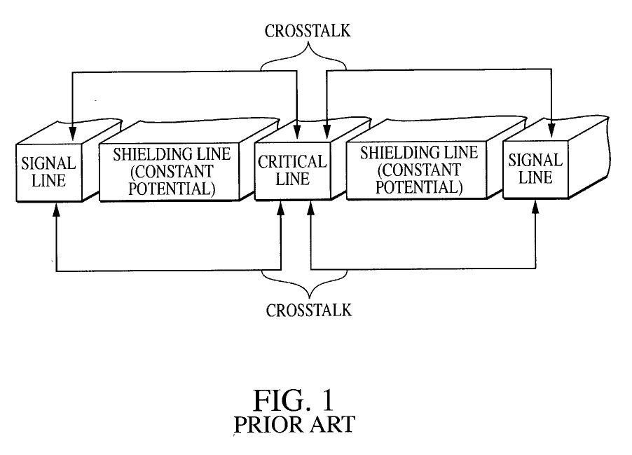

FIG. 2 is a schematic diagram of a shielding line system for an integrated circuit according to an embodiment.

FIG. 3 is a schematic diagram of a shielding line system for an integrated circuit according to another embodiment.

FIG. 4 is a flowchart of an embodiment of a method for shielding a conductive line in an integrated circuit.

### DETAILED DESCRIPTION OF THE PREFERRED EMBODIMENTS

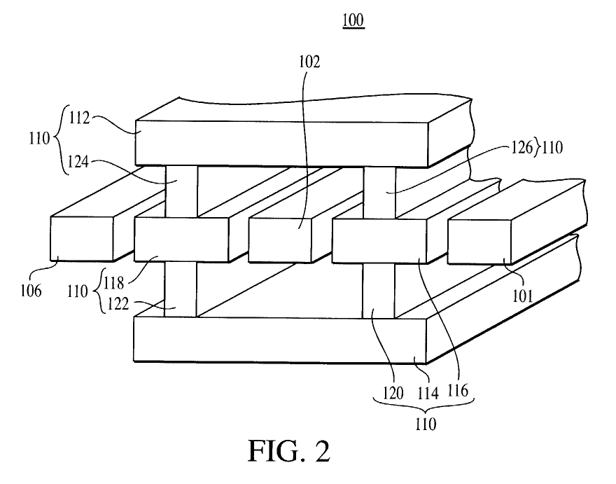

FIG. 2 is a schematic diagram of a shielding line system 100 for an integrated circuit according to an embodiment. The shielding line system 100 includes a critical line 102, signal lines 106 and 108, and a shielding line conduit 110. There may be one or other multiples of signal lines. Critical line 102 carries timing signals or reference voltages. Signal lines 106 and 108 carry data, control signals, or other signals. The critical and signal lines may carry other signals and the same or similar signals for the integrated circuit. The shielding line conduit 110 is disposed between the critical line 102 and signal lines 106 and 108. The shielding line conduit 110 reduces or eliminates crosstalk between the critical line 102 and signal lines 106 and 108. The integrated circuit may be a memory device such as a dynamic random access memory (DRAM) or another semiconductor device. While particular configurations have been shown and described, other configurations may be used including those with fewer or additional components such as just critical lines shielded from external interference.

Critical line 102, signal lines 106 and 108, and shielding line conduit 110 are conductive channels or lines, which are combined with electrical components (resistors, capacitors, transistors, and like) to create an integrated circuit. The electrical components and conductive channels are formed on a semiconductor wafer using a photolithographic or similar process for manufacturing integrated circuits. The semiconductor wafer usually is a single crystal silicon wafer; however germanium, gallium arsenide, and other semiconductor materials may be used. To fabricate the integrated circuit, the various materials comprising the finished circuit are layered onto the semiconductor wafer. These materials include conductive materials, dielectrics, and the like. After each layer, photoresist and etching processes are used to form the layer into the desired configuration. A photoresist material is applied to portions of the layer that remain on the semiconductor wafer. The etching process removes portions of the layer not protected by the photoresist material. The photoresist material is removed and another layer is formed on the semiconductor wafer. The conductive channels are separated by dielectric materials.

The shielding line conduit 110 has a top shielding line 112, a bottom shielding line 114, a first side shielding line 116, and a second side shielding line 118. The top shielding line 112 is connected to the first side shielding line 116 by a first line contact or via 126. The top shielding line 112 is connected to the second side shielding line 118 by a second line contact or via 124. The bottom shielding line 114 is connected to the first side shielding line 116 by a third line contact or via 120. The bottom shielding line 114 is connected to the second side shielding line 118 by a fourth line contact or via 122.

The top and bottom shielding lines 112 and 114 are on opposite sides of the critical line 102. The first and second side shielding lines 116 and 118 are on opposite sides of critical line 102. The first and second side shielding lines 116 and 118 also are adjacent to critical line 102. The shielding lines 112, 114, 116, and 118 and critical line 102 may have one or more lines or other components between any or all of them.

The shielding line conduit 110 forms a rectangular shape that radially encloses critical line 102. The shielding line conduit 110 may extend longitudinally along a portion or the entire length of critical line 102. Shielding line conduit 110 has constant potential, thus creating an electromagnetic field that also radially encloses critical line 102. The electromagnetic field may extend longitudinally along the entire length or a portion of the critical line 102. The electromagnetic field may be continuous (present whenever the integrated circuit is operating) or may be intermittent (present only when critical line 102 is carrying a signal). The radial enclosure of the critical line 102 by the shielding line conduit 110 and the electromagnetic field reduces or eliminates any crosstalk between critical line 102 and signal lines 106 and 108. Shielding line conduit 110 may have other shapes and have other electromagnetic fields that reduce or eliminate cross talk. While the arrangement of the critical line 102 and shielding line conduit 110 has been described, they may have other arrangements as long as the mechanical and/or electromagnetic properties to reduce or eliminate crosstalk are achieved.

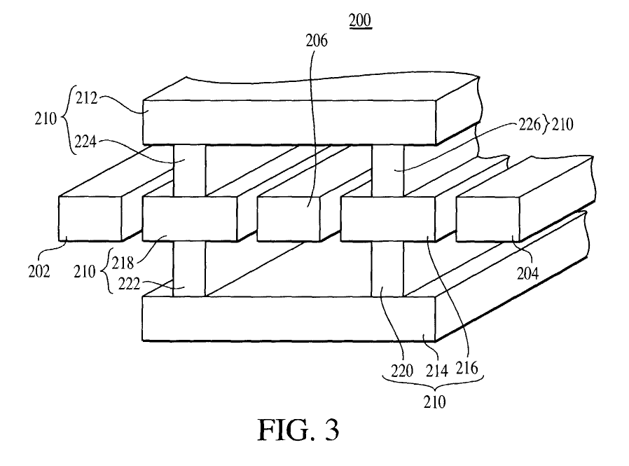

FIG. 3 is a schematic diagram of a shielding line system 200 for an integrated circuit according to another embodiment. The shielding line system 200 includes a signal line 206, critical lines 202 and 204, and a shielding line conduit 210. There may be one or other multiples of critical lines. Critical lines 202 and 204, signal line 206, and shielding line conduit 210 are conductive channels or lines as previously discussed. Critical lines 202 and 204 carry timing signals or reference voltages. Signal line 206 carries data and control signals. The critical and signal lines may carry other signals and the same or similar signals for the integrated circuit. The shielding line conduit 210 is disposed between the critical lines 202 and 204 and signal line 206. The shielding line conduit 210 reduces or eliminates crosstalk between the critical lines 202 and 204 and signal line 206. The integrated circuit may be a memory device such as a dynamic random access memory (DRAM) or another semiconductor device. While particular configurations have been shown and described, other configurations may be used including those with fewer or additional components.

The shielding line conduit 210 has a top shielding line 212, a bottom shielding line 214, a first side shielding line 216, and a second side shielding line 218. The top shielding line 212 is connected to the first side shielding line 216 by a first line contact or via 226. The top shielding line 212 is connected to the second side shielding line 218 by a second line contact or via 224. The bottom shielding line 214 is connected to the first side shielding line 216 by a third line contact or via 220. The bottom shielding line 214 is connected to the second side shielding line 218 by a fourth line contact or via 222.

The top and bottom shielding lines 212 and 214 are on opposite sides of the signal line 206. The first and second side shielding lines 216 and 218 are on opposite sides of signal line 206. The first and second side shielding lines 216 and 218 also are adjacent to signal line 206. The shielding lines 212, 214, 216, and 218 and signal line 206 may have one or more lines or other components between any or all of them.

The shielding line conduit 210 forms a rectangular shape that radially encloses signal line 206. The shielding line conduit 210 may extend longitudinally along a portion or the entire length signal line 206. Shielding line conduit 210 has constant potential, thus creating an electromagnetic field that also radially encloses signal line 206. The electromagnetic field may extend longitudinally along the entire length or a portion of the signal line 206. The electromagnetic field may be continuous (present whenever the integrated circuit is operating) or may be intermittent (present only when signal line 206 is carrying a signal). The radial enclosure of the signal line 206 by the electromagnetic field and the shielding line conduit 210 reduces or eliminates any crosstalk between critical lines 202 and 204 and signal line 206. Shielding line conduit 210 may have other shapes and have other electromagnetic fields that reduce or eliminate cross talk. While the arrangement of signal line 206 and shielding line conduit 210 has been described, they may have other arrangements as long as the mechanical and/or electromagnetic properties to reduce or eliminate crosstalk are achieved.

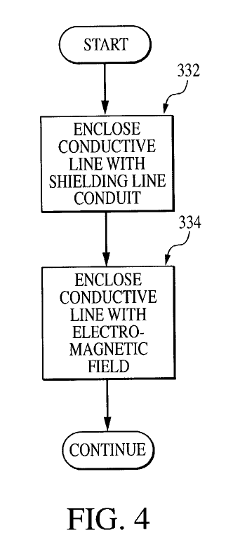

FIG. 4 is a flowchart of an embodiment of a method for shielding a conductive line in an integrated circuit. A conductive line is radially enclosed 332 by a shielding line conduit as previously discussed. The conductive line may be a signal line or a critical line. The shielding line conduit may have top and bottom shield lines, first and second shield lines, and side line vias. The shielding line conduit may have another configuration and/or arrangement including fewer or additional components. The shielding line conduit may extend a portion or the entire length of the conductive line. The conductive line is radially enclosed 334 by an electromagnetic field as previously discussed. The electromagnetic field may extend the entire length or a portion of the conductive line. The electromagnetic field may be continuous (present whenever the integrated circuit is operating) or may be intermittent (present only when the conductive line is carrying a signal).

Various embodiments of the invention have been described and illustrated. However, the description and illustrations are by way of example only. Other embodiments and implementations are possible within the scope of this invention and will be apparent to those of ordinary skill in the art. Therefore, the invention is not limited to the specific details, representative embodiments, and illustrated examples in this description. Accordingly, the invention is not to be restricted except in light as necessitated by the accompanying claims and their equivalents.

What is claimed is:

1. A shielding line system for an integrated circuit, comprising:
a first conductive line;
a shielding line conduit disposed around the first conductive line, where the shielding line conduit radially encloses the first conductive line, and where an electromagnetic field radially encloses the first conductive line, and semiconductor material separating the first conductive line from the shielding line conduit.

2. The shielding line system according to claim 1, where the first conductive line is a critical line, and where the at least one second conductive line is a signal line.

3. The shielding line system according to claim 1, where the first conductive line is a signal line, and where the at least one second conductive line is a critical line.

4. The shielding line system according to claim 1, where the shielding line conduit extends longitudinally along at least a portion of the first conductive line.

5. The shielding line system according to claim 1, where the electromagnetic field extends longitudinally along at least a portion of the first conductive line.

6. The shielding line system according to claim 1, where the electromagnetic field is continuous.

7. The shielding line system according to claim 1, where the electromagnetic field is intermittent.

8. The shielding line system according to claim 1, where the shielding line conduit further comprises:
a top shielding line;
a first side shielding line connected to the top shielding line;
a second side shielding line connected to the top shielding line; and
a bottom shielding line connected to the first and second shielding lines.

9. The shielding line system according to claim 8, where the first and second shielding lines are on opposite sides of the first conductive line.

10. The shielding line system according to claim 8, where the top and bottom shielding lines are on opposite sides of the first conductive line.

11. The shielding line system according to claim 8, where at least one of the first and second side shielding lines is disposed between the first conductive line and the at least one second conductive line.

12. The shielding line system according to claim 8, where the top and bottom shielding lines and the first and second side shielding lines form a rectangular shape.

13. A shielding line system for an integrated circuit, comprising:
a first conductive line;
a second conductive line;
a third conductive line;
a first side shielding line disposed between the first and second conductive lines;
a second side shielding line disposed between the first and third conductive lines;
a top shielding line connected to the first and second shielding lines; and
a bottom shielding line connected to the first and second shielding lines; and
where an electromagnetic field radially encloses the first conductive line.

14. The shielding line system according to claim 13, where the first conductive line is a critical line, and where the second and third conductive lines are signal lines.

15. The shielding line system according to claim 13, where the first conductive line is a signal line, and where the second and third conductive lines are critical lines.

16. The shielding line system according to claim 13, where the electromagnetic field extends longitudinally along at least a portion of the first conductive line.

17. The shielding line system according to claim 13, where the electromagnetic field is continuous.

18. The shielding line system according to claim 13, where the electromagnetic field is intermittent.

19. The shielding line system according to claim 13, where the first and second shielding lines are on opposite sides of the first conductive line.

20. The shielding line system according to claim 13, where the top and bottom shielding lines are on opposite sides of the first conductive line.

21. A method for shielding a conductive line in an integrated circuit, comprising:
radially enclosing a conductive line with a shielding line conduit; and
radially enclosing the conductive line with an electromagnetic field.

22. The method according to claim 21, where the conductive line is a critical line.

23. The method according to claim 21, where the conductive line is a signal line.

24. The method according to claim 21, further comprising extending the shielding line conduit longitudinally along at least a portion of the conductive line.

25. The method according to claim 21, further comprising extending the electromagnetic field longitudinally along at least a portion of the conductive line.

26. The method according to claim 21, further comprising maintaining a continuous electromagnetic field.

27. The method according to claim 21, further comprising maintaining an intermittent electromagnetic field.
